(19) United States
(12) Patent Application Publication
(10) Pub. No.: US 2025/0275056 A1
(43) Pub. Date: Aug. 28, 2025

(54) INTEGRATED LASER CAVITY NETWORK WITH PRINTED CIRCUIT BOARD

(71) Applicant: DeUVe Photonics, Inc., Tucson, AZ (US)

(72) Inventors: Chris Hessenius, Tucson, AZ (US); Mahmoud Fallahi, Tucson, AZ (US)

(21) Appl. No.: 19/060,105

(22) Filed: Feb. 21, 2025

Related U.S. Application Data
(60) Provisional application No. 63/557,856, filed on Feb. 26, 2024.
(60) Provisional application No. 63/572,838, filed on Apr. 1, 2024.

(51) Int. Cl. H05K 1/02; H01S 5/0237; H01S 5/40; H05K 1/14

(52) U.S. Cl. CPC H05K 1/0274; H05K 1/144; H01S 5/0237; H01S 5/4025; H05K 2201/042; H05K 2201/10121; H05K 2201/10151

(57) ABSTRACT

A circuit board-based laser cavity system. The system may comprise a bottom printed circuit board (PCB). The bottom PCB may comprise an enclosed laser cavity network. The laser cavity network may comprise one or more laser channels, and one or more gain chips disposed within the one or more laser channels, configured to generate one or more laser beams within the one or more laser channels. The laser cavity network may further comprise one or more mirrors disposed within the one or more laser channels, configured to direct the one or more laser beams through the one or more laser channels. The one or more laser channels, the one or more gain chips, and the one or more mirrors may be soldered to the bottom PCB.

### CROSS-REFERENCE TO RELATED APPLICATIONS

This application is a non-provisional and claims benefits of U.S. Provisional Application No. 63/557,856 filed Feb. 26, 2024 and U.S. Provisional Application No. 63/572,838 filed Apr. 1, 2024, the specifications of which are incorporated herein in their entirety by reference.

### FIELD OF THE INVENTION

The present invention is directed to a circuit board comprising a laser system directly applied to the board.

### BACKGROUND OF THE INVENTION

Circuit boards are typically used with electronic components. However, prior systems have been unable to integrate laser systems into circuit boards efficiently. Many electrical elements are needed to make lasers and laser-based sensors operate, such as current drivers, electro-optic devices, thermoelectric coolers, frequency stabilization devices, pulse modulators, electromagnetic devices, MEMS devices, photodiodes, etc. Thus, there exists a present need for a circuit board system implementing a laser system directly on the board.

### BRIEF SUMMARY OF THE INVENTION

It is an objective of the present invention to provide systems that allow for a circuit board comprising a laser system directly applied to the board, as specified in the independent claims. Embodiments of the invention are given in the dependent claims. Embodiments of the present invention can be freely combined with each other if they are not mutually exclusive.

In the present invention, a top and bottom PCB board can create an enclosure for the laser network and provide an economical and effective basis for constructing a wide variety of lasers and laser-based sensors including high-power lasers, UV laser sources, and sensors such as laser-based magnetometers. The top and bottom PCBs not only provide positive and negative electrical terminals to laser cavity components (if needed), but also house all electrical components, add structural integrity to the device, and provide a housing for the laser network.

The present invention features a circuit board system. In some embodiments, the system may comprise a bottom printed circuit board (PCB). The bottom PCB may comprise an enclosed laser cavity network. The laser cavity network may comprise one or more laser channels, and one or more gain chips disposed within the one or more laser channels, configured to generate one or more laser beams within the one or more laser channels. The laser cavity network may further comprise one or more mirrors disposed within the one or more laser channels, configured to direct the one or more laser beams through the one or more laser channels. The one or more laser channels, the one or more gain chips, and the one or more mirrors may be soldered to the bottom PCB.

The present invention may allow for efficiently sized laser systems, able to be implemented in small spaces for photonic functionalities on a micro-scale. Furthermore, the present invention may further allow for efficient integration between photonics and electronics for increased versatility and modularity of photonic-electronic chips. This may also allow for the integration of photonic devices into existing electronic systems

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE SEVERAL VIEWS OF THE DRAWING(S)

The features and advantages of the present invention will become apparent from a consideration of the following detailed description presented in connection with the accompanying drawings in which:

FIG. 1 shows a first embodiment of the integrated laser cavity network of the present invention comprising a bottom printed circuit board.

FIG. 2 shows a second embodiment of the integrated laser cavity network of the present invention comprising a top printed circuit board and a bottom printed circuit board.

FIG. 3 shows a schematic diagram of the laser cavity network of the present invention comprising laser channels, gain chips, mirrors, sensing media, electrical components, and optical components.

### DETAILED DESCRIPTION OF THE INVENTION

Following is a list of elements corresponding to a particular element referred to herein:
100 system
110 bottom printed circuit board (PCB)
200 laser cavity network
210 laser channels
220 gain chips
230 mirrors
240 sensing media
250 electrical components
260 optical components
300 top PCB

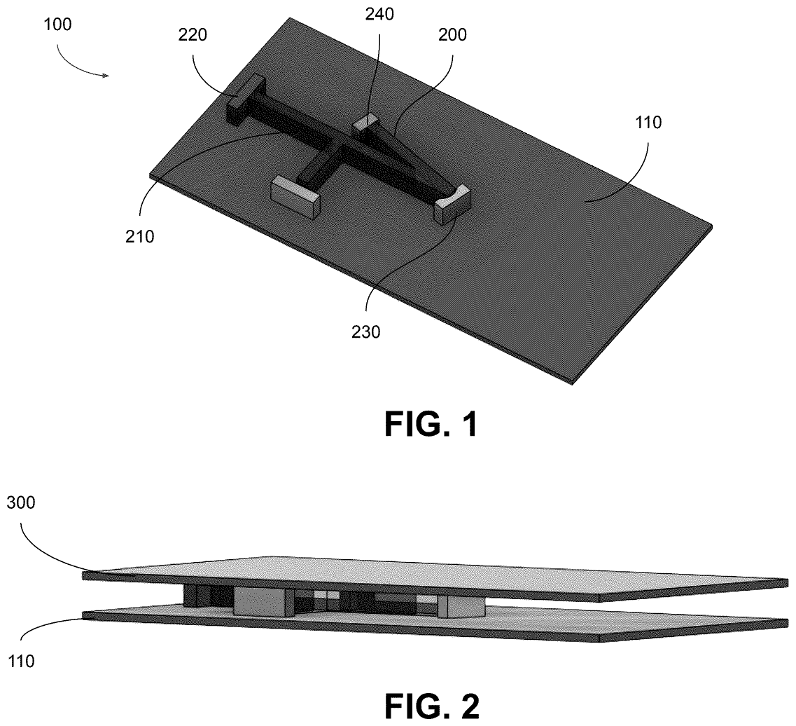

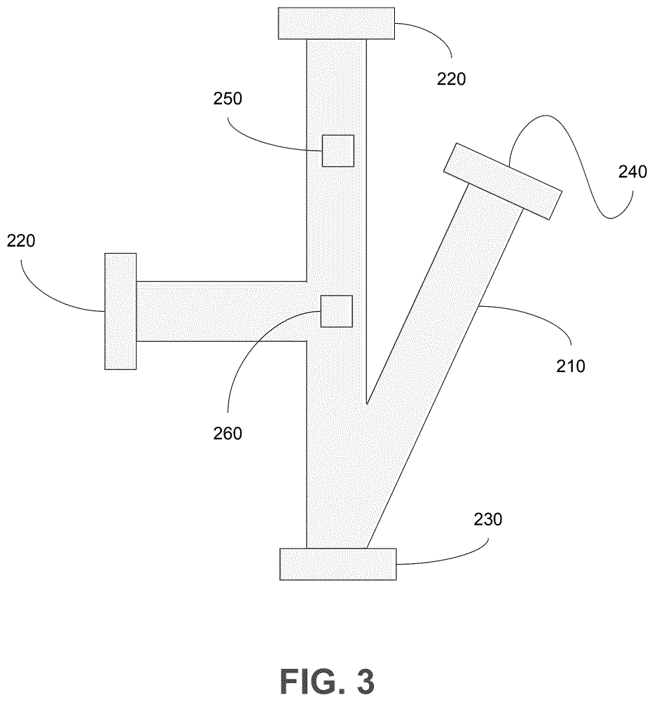

Referring now to FIGS. 1-3, the present invention features a circuit board system (100). In some embodiments, the system (100) may comprise a bottom printed circuit board (PCB) (110). The bottom PCB (110) may comprise an enclosed laser cavity network (200). The laser cavity network (200) may comprise one or more laser channels (210), and one or more gain chips (220) disposed within the one or more laser channels (210), configured to generate one or more laser beams within the one or more laser channels (210). The laser cavity network (200) may further comprise one or more mirrors (230) disposed within the one or more laser channels (210), configured to direct the one or more laser beams through the one or more laser channels (210). The one or more laser channels (210), the one or more gain chips (220), and the one or more mirrors (230) may be soldered to the bottom PCB (110).

In some embodiments, the one or more laser channels (210), the one or more gain chips (220), and the one or more mirrors (230) may be soldered to the bottom PCB (110) by one or more solder pads. In some embodiments, the enclosed laser cavity network (200) may further comprise one or more electrical components (250) soldered to the bottom PCB (110), configured to power and modulate the one or more gain chips (220). In some embodiments, the one or more electrical components (250) may comprise current drivers, electro-optic devices, thermoelectric coolers, frequency stabilization devices, pulse modulators, electromagnetic devices, micro-electro-mechanical system (MEMS) devices, photodiodes, or a combination thereof.

In some embodiments, the enclosed laser cavity network (200) may further comprise one or more optical components (260) soldered to the bottom PCB (110), configured to modulate the one or more laser beams. In some embodiments, the one or more optical components (260) may comprise nonlinear optics, mirrors, lenses, fiber, frequency selective elements, beamsplitters, output couplers, waveguides, or a combination thereof. In some embodiments, the enclosed laser cavity network (200) may further comprise a glass material. In some embodiments, the system (100) may further comprise a top PCB (300) disposed on top of the enclosed laser cavity network (200). The one or more laser channels (210), the one or more gain chips (220), and the one or more mirrors (230) may be soldered to the top PCB (300).

In some embodiments, the one or more gain chips may be configured to generate one or more high-power laser beams, one or more ultraviolet laser beams, one or more higher-order laser beams, or a combination thereof. In some embodiments, the enclosed laser cavity may further comprise one or more sensing media (240) soldered to the bottom PCB (110), configured to measure one or more properties based on the one or more laser beams. In some embodiments, the one or more sensing media (240) may further comprise one or more laser-based magnetometers.

In some embodiments, any number of laser cavities may be implemented on top of the bottom PCB. In some embodiments, each laser cavity network disposed on top of the bottom PCB may comprise any shape having any number of bends and any number of ends. In some embodiments, each laser cavity network disposed on top of the bottom PCB may comprise any number of gain chips, any number of mirrors, any number of sensing media, and any number of additional optical components. In some embodiments, each laser cavity network disposed on top of the bottom PCB may be coupled to any number of electrical components. In some embodiments, the top PCB may further comprise any number of laser cavity networks disposed on top of the top PCB. The system of the present invention may be stacked such that any number of laser cavity PCBs and any number of electronic components can be stacked in any order and to any height.

In some embodiments, the one or more electrical components (250) soldered to the bottom PCB (110) may be adjacent to the laser cavity network (200). In some embodiments, the one or more optical components (260) soldered to the bottom PCB (110) may be within the laser cavity network (200). In some embodiments, the one or more laser channels (210) may be configured to intersect. In some embodiments, at least one of the one or more mirrors (230) may be disposed at an intersection of the one or more laser channels (210). In some embodiments, the one or more laser channels (210) may comprise one or more ends. The one or more gain chips (220) may be disposed at the one or more ends of the one or more laser channels (210).

It is to be noted that the present invention is not equivalent to a photonic integrated circuit (IC). The present invention implements a laser cavity network integrated into a printed circuit board. In the laser cavity network of the present invention, the laser is generated from components on top of the circuit board itself, whereas in photonic ICs, the laser is directed towards a chip from an external source away from the chip.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting essentially of” or “consisting of”, and as such the written description requirement for claiming one or more embodiments of the present invention using the phrase “consisting essentially of” or “consisting of” is met.

The reference numbers recited in the below claims are solely for ease of examination of this patent application, and are exemplary, and are not intended in any way to limit the scope of the claims to the particular features having the corresponding reference numbers in the drawings.

What is claimed is:

1. A circuit board system (100) comprising a bottom printed circuit board (PCB) (110) comprising an enclosed laser cavity network (200) comprising:
a. one or more laser channels (210);
b. one or more gain chips (220) disposed within the one or more laser channels (210), configured to generate one or more laser beams within the one or more laser channels (210); and
c. one or more mirrors (230) disposed within the one or more laser channels (210), configured to direct the one or more laser beams through the one or more laser channels (210);
wherein the one or more laser channels (210), the one or more gain chips (220), and the one or more mirrors (230) are soldered to the bottom PCB (110).

2. The system (100) of claim 1, wherein the one or more laser channels (210), the one or more gain chips (220), and the one or more mirrors (230) are soldered to the bottom PCB (110) by one or more solder pads.

3. The system (100) of claim 1, wherein the enclosed laser cavity network (200) further comprises one or more electrical components (250) soldered to the bottom PCB (110) adjacent to the laser cavity network (200), configured to power and modulate the one or more gain chips (220).

4. The system (100) of claim 3, wherein the one or more electrical components (250) comprise current drivers, electro-optic devices, thermoelectric coolers, frequency stabilization devices, pulse modulators, electromagnetic devices, micro-electro-mechanical system (MEMS) devices, photodiodes, or a combination thereof.

5. The system (100) of claim 1, wherein the enclosed laser cavity network (200) further comprises one or more optical components (260) soldered to the bottom PCB (110) within the laser cavity network (200), configured to modulate the one or more laser beams.

6. The system (100) of claim 5, wherein the one or more optical components (260) comprise nonlinear optics, mirrors, lenses, fiber, frequency selective elements, beamsplitters, output couplers, waveguides, or a combination thereof.

7. The system (100) of claim 1, wherein the enclosed laser cavity network (200) further comprises a glass material.

8. The system (100) of claim 1 further comprising a top PCB (300) disposed on top of the enclosed laser cavity network (200), wherein the one or more laser channels (210), the one or more gain chips (220), and the one or more mirrors (230) are soldered to the top PCB (300).

9. The system (100) of claim 1, wherein the one or more gain chips are configured to generate one or more high-power laser beams, one or more ultraviolet laser beams, one or more higher-order laser beams, or a combination thereof.

10. The system (100) of claim 1, wherein the one or more laser channels (210) are configured to intersect.

11. The system (100) of claim 10, wherein at least one of the one or more mirrors (230) are disposed at an intersection of the one or more laser channels (210).

12. The system (100) of claim 1, wherein the one or more laser channels (210) comprise one or more ends, wherein the one or more gain chips (220) are disposed at the one or more ends of the one or more laser channels (210).

13. The system (100) of claim 1, wherein the enclosed laser cavity further comprises one or more sensing media (240) soldered to the bottom PCB (110), configured to measure one or more properties based on the one or more laser beams.

14. The system (100) of claim 12, wherein the enclosed laser cavity further comprises one or more sensing media (240) soldered to the bottom PCB (110), configured to measure one or more properties based on the one or more laser beams, wherein the one or more sensing media (240) are disposed at the one or more ends of the one or more laser channels (210).

15. The system (100) of claim 13, wherein the one or more sensing media (240) further comprise one or more laser-based magnetometers.

16. A circuit board system (100) comprising:
a. a bottom printed circuit board (PCB) (110) comprising an enclosed laser cavity network (200) comprising:
i. one or more laser channels (210);
ii. one or more gain chips (220) disposed within the one or more laser channels (210), configured to generate one or more laser beams within the one or more laser channels (210);
iii. one or more mirrors (230) disposed within the one or more laser channels (210), configured to direct the one or more laser beams through the one or more laser channels (210); and
iv. one or more sensing media (240) soldered to the bottom PCB (110), configured to measure one or more properties based on the one or more laser beams;
wherein the one or more laser channels (210), the one or more gain chips (220), the one or more mirrors (230), and the one or more sensing media (240) are soldered to the bottom PCB (110); and
b. a top PCB (300) disposed on top of the enclosed laser cavity network (200) such that the one or more laser channels (210), the one or more gain chips (220), the one or more mirrors (230), and the one or more sensing media (240) are soldered to the top PCB (300).

17. The system (100) of claim 16, wherein the one or more laser channels (210), the one or more gain chips (220), the one or more mirrors (230), and the one or more sensing media (240) are soldered to the bottom PCB (110) by one or more solder pads.

18. The system (100) of claim 16, wherein the enclosed laser cavity network (200) further comprises one or more electrical components (250) soldered to the bottom PCB (110), configured to power and modulate the one or more gain chips (220), the one or more electrical components (250) comprising current drivers, electro-optic devices, thermoelectric coolers, frequency stabilization devices, pulse modulators, electromagnetic devices, micro-electro-mechanical system (MEMS) devices, photodiodes, or a combination thereof.

19. The system (100) of claim 16, wherein the enclosed laser cavity network (200) further comprises one or more optical components (260) soldered to the bottom PCB (110), configured to modulate the one or more laser beams, the one or more optical components (260) comprising nonlinear optics, mirrors, lenses, fiber, frequency selective elements, beamsplitters, output couplers, waveguides, or a combination thereof.

20. The system (100) of claim 16, wherein the enclosed laser cavity network (200) further comprises a glass material.

21. A circuit board system (100) comprising:
a. a bottom printed circuit board (PCB) (110) comprising an enclosed laser cavity network (200) comprising:
i. one or more laser channels (210);
ii. one or more gain chips (220) disposed within the one or more laser channels (210), configured to generate one or more laser beams within the one or more laser channels (210);
iii. one or more mirrors (230) disposed within the one or more laser channels (210), configured to direct the one or more laser beams through the one or more laser channels (210);
iv. one or more sensing media (240) soldered to the bottom PCB (110), configured to measure one or more properties based on the one or more laser beams;
v. one or more electrical components (250) soldered to the bottom PCB (110), configured to power and modulate the one or more gain chips (220); and
vi. one or more optical components (260) soldered to the bottom PCB (110), configured to modulate the one or more laser beams;
wherein the one or more laser channels (210), the one or more gain chips (220), the one or more mirrors (230), the one or more sensing media (240), the one or more electrical components (250), and the one or more optical components (260) are soldered to the bottom PCB (110); and
b. a top PCB (300) disposed on top of the enclosed laser cavity network (200) such that the one or more laser channels (210), the one or more gain chips (220), the one or more mirrors (230), the one or more sensing media (240), the one or more electrical components (250), and the one or more optical components (260) are soldered to the top PCB (300).
